(19) United States
(12) Patent Application Publication
(10) Pub. No.: US 2011/0169115 A1
(43) Pub. Date: Jul. 14, 2011

(54) Wireless Communication Device for Remote Authenticity Verification of Semiconductor Chips, Multi-Chip Modules and Derivative Products

(75) Inventor: Chang-Ming Lin, San Jose, CA (US)

(73) Assignee: RFMARQ, INC., Monte Sereno, CA (US)

(21) Appl. No.: 13/005,336

(22) Filed: Jan. 12, 2011

Related U.S. Application Data
(60) Provisional application No. 61/295,159, filed on Jan. 14, 2010.

(51) Int. Cl. H01L 23/02

(52) U.S. Cl. 257/428; 257/E23.18

(57) ABSTRACT

A semiconductor package includes a package body with a cavity housing a first integrated circuit die. A wireless tag including a wireless element and an antenna is embedded in the semiconductor package. In one embodiment, the antenna is embedded in the package body of the semiconductor package. In another embodiment, the antenna is formed on or in the first integrated circuit die housed in the semiconductor package. According to another aspect of the present invention, the semiconductor package may be mounted on a printed circuit board and a second antenna is formed on the printed circuit board in electrical connection to the antenna embedded in the semiconductor package.

### CROSS-REFERENCE TO RELATED APPLICATIONS

This application claims the benefit of U.S. Provisional Patent Application Ser. No. 61/295,159, filed on Jan. 14, 2010, which application is incorporated herein by reference in its entirety.

### FIELD OF THE INVENTION

The invention relates to wireless communication devices and, in particular, the invention relates to wireless communication devices embedded in semiconductor packages.

### DESCRIPTION OF THE RELATED ART

Consumer electronic products can be tagged using electronic tracking devices or electronic tags to store product identity or other product information to allow the products to be tracked through the manufacturing process or through the supply and distribution chain. Electronic tags are electronically read by electronic readers (communicators) when the tags are within the communication range.

Radio frequency identification (RFID) technology is an electronic tracking technology commonly employed to track products and their movements. An RFID tag includes a wireless transceiver device and an antenna to enable radio frequency (RF) communication between the RFID tag and an RFID reader when the reader is brought within a communication range of the tag. The RFID transceiver device includes storage elements for storing identity or product information, and a circuit to receive incoming signals, generate response signals and transmit the response signals.

When RFID tags are affixed to electronic products, the RFID tags are often subject to easy tampering. For example, if the RFID tag is merely placed on the chassis or even on internal printed circuit board of an electronic product, the RFID tag can be removed to prevent tracking of the product.

Furthermore, the sensitivity of an RFID tag is related to the size of the antenna. For passive RFID tags that are driven by the electric energy converted from electro-magnetic wave via the antenna loop, the antenna loop is often designed with as large loop cross-section as possible to support the required power. This makes RFID tag large in size and unsuitable for applications with limited real estate because that incorporation of a large antenna is not feasible.

### SUMMARY OF THE INVENTION

According to one embodiment of the present invention, a semiconductor package includes a package body including a cavity, a first integrated circuit die housed in the cavity and electrically connected to leads of the semiconductor package, a wireless element including a wireless transceiver and a memory circuit both formed on a second integrated circuit die where the wireless element is housed in the semiconductor package, and an antenna embedded in the package body and electrically connected to the wireless element. The wireless transceiver and the antenna operate in conjunction to enable the information stored in the memory circuit to be accessed through wireless communication.

According to another embodiment of the present invention, a semiconductor package includes a package body including a cavity, a first integrated circuit die housed in the cavity and electrically connected to leads of the semiconductor package, a wireless element including a wireless transceiver and a memory circuit both formed on a second integrated circuit die where the wireless element is housed in the semiconductor package, and an antenna formed on or in the first integrated circuit die and electrically connected to the wireless element. The wireless transceiver and the antenna operate in conjunction to enable the information stored in the memory circuit to be accessed through wireless communication.

According to yet another embodiment of the present invention, a printed circuit board includes one or more semiconductor packages mounted thereon where each semiconductor package houses an integrated circuit die, a first semiconductor package including a first integrated circuit die electrically connected to leads of the semiconductor package, a wireless element including a wireless transceiver and a memory circuit both formed on a second integrated circuit die where the wireless element is housed in the semiconductor package, and a first antenna embedded in the package body and electrically connected to the wireless element. The printed circuit board further includes a second antenna formed in the printed circuit board and being electrically connected to the first antenna. The wireless transceiver and the first and second antennas operate in conjunction to enable the information stored in the memory circuit to be accessed through wireless communication.

### BRIEF DESCRIPTION OF THE DRAWINGS

FIGS. 1(a) and 1(b) are top and cross-sectional views, respectively, of a semiconductor package incorporating a wireless communication device (“a wireless tag”) formed using the antenna integration method according to a first embodiment of the present invention.

FIGS. 2(a) and 2(b) are top and cross-sectional views, respectively, of a semiconductor package incorporating a wireless communication device (“a wireless tag”) formed using the antenna integration method according to a second embodiment of the present invention.

FIGS. 3(a) and 3(b) are top and cross-sectional views, respectively, of a semiconductor package incorporating a wireless communication device (“a wireless tag”) formed using the antenna integration method according to a third embodiment of the present invention.

FIGS. 4(a) and 4(b) are top and cross-sectional views, respectively, of a semiconductor package incorporating a wireless communication device (“a wireless tag”) formed using the antenna integration method according to a fourth embodiment of the present invention.

FIGS. 5(a) and 5(b) are perspective and cross-sectional views, respectively, of a semiconductor package incorporating a wireless communication device (“a wireless tag”) formed using the antenna integration method according to a fifth embodiment of the present invention.

FIGS. 6(a) and 6(b) are perspective and cross-sectional views, respectively, of a semiconductor package incorporating a wireless communication device (“a wireless tag”) formed using the antenna integration method according to a sixth embodiment of the present invention.

FIGS. 7(a) and 7(b) are perspective and cross-sectional views, respectively, of a semiconductor package incorporating a wireless communication device (“a wireless tag”) formed using the antenna integration method according to a seventh embodiment of the present invention.

FIGS. 8(a) and 8(b) are perspective and cross-sectional views, respectively, of a semiconductor package incorporating a wireless communication device (“a wireless tag”) formed using the antenna integration method according to an eighth embodiment of the present invention.

FIGS. 9(a) and 9(b) are perspective and cross-sectional views, respectively, of a semiconductor package incorporating a wireless communication device (“a wireless tag”) formed using the antenna integration method according to a ninth embodiment of the present invention.

FIGS. 10(a) and 10(b) are perspective and cross-sectional views, respectively, of a semiconductor package incorporating a wireless communication device (“a wireless tag”) formed using the antenna integration method according to a tenth embodiment of the present invention.

FIGS. 11(a) and 11(b) are top and cross-sectional views, respectively, of a printed circuit board with extended antenna structure incorporating a semiconductor package incorporating a wireless communication device (“a wireless tag”) formed using the antenna integration method and according to an eleventh embodiment of the present invention.

### DETAILED DESCRIPTION OF THE PREFERRED EMBODIMENTS

According to one aspect of the present invention, a method for forming a wireless communication device for tracking an integrated circuit die housed in a semiconductor package includes forming an antenna structure for the wireless communication device in the package body of the semiconductor package. The wireless communication devices further includes a wireless element having a wireless transceiver and a memory formed thereon and attached to either the integrated circuit die or the package body of the semiconductor package. The wireless element is electrically connected to the antenna structure to form a wireless communication device having improved signal reception and sensitivity capability.

According to another aspect of the present invention, a method for forming a wireless communication device for tracking an integrated circuit die housed in a semiconductor package includes forming an antenna structure for the wireless communication device on or in the integrated circuit die. The wireless communication devices further includes a wireless element having a wireless transceiver and a memory formed thereon and attached to the integrated circuit die. The wireless element is electrically connected to the antenna structure to form a wireless communication device having improved signal reception and sensitivity capability.

A particular advantage of the wireless communication device of the present invention is that the entire wireless communication device can be fitted into a device with limited real estate, such as a semiconductor package. The wireless communication device makes efficient use of available space of the device to implement the antenna structure. In this manner, wireless tracking capability can be realized in applications with limited real estate, such as semiconductor packages.

In the present description, a wireless communication device, also referred to as “a wireless tag,” including a wireless transceiver, a memory and an antenna. The wireless transceiver and the memory, referred to collectively as a “wireless element,” are typically formed in a single integrated circuit die. In the present description, a wireless element refers to the combination of the wireless transceiver circuit and the memory circuit and may be formed in one or more integrated circuit die.

The antenna integration method of the present invention can be adapted for use in a variety of semiconductor package types to enable feasible and low cost tracking and authentication function to be implemented. In some embodiments, the antenna integration method is applied in lid-sealed cavity integrated circuit packages. Lid-sealed cavity integrated circuit packages include cavity-up or cavity-down plastic ball grid array (PBGA) packages, cavity-up or cavity-down ceramic ball grid array (CBGA) packages, cavity-up or cavity-down ceramic column grid array (CCGA) packages, cavity-up or cavity-down ceramic pin grid array (CPGA) packages, and other similar IC packages. In most cases, the package body of the plastic or ceramic BGA or CGA packages are formed using fine pitch printed circuit board (PCB) type materials and the package body has a multi-layer interconnect structure with interleaving thin metal films and dielectric films.

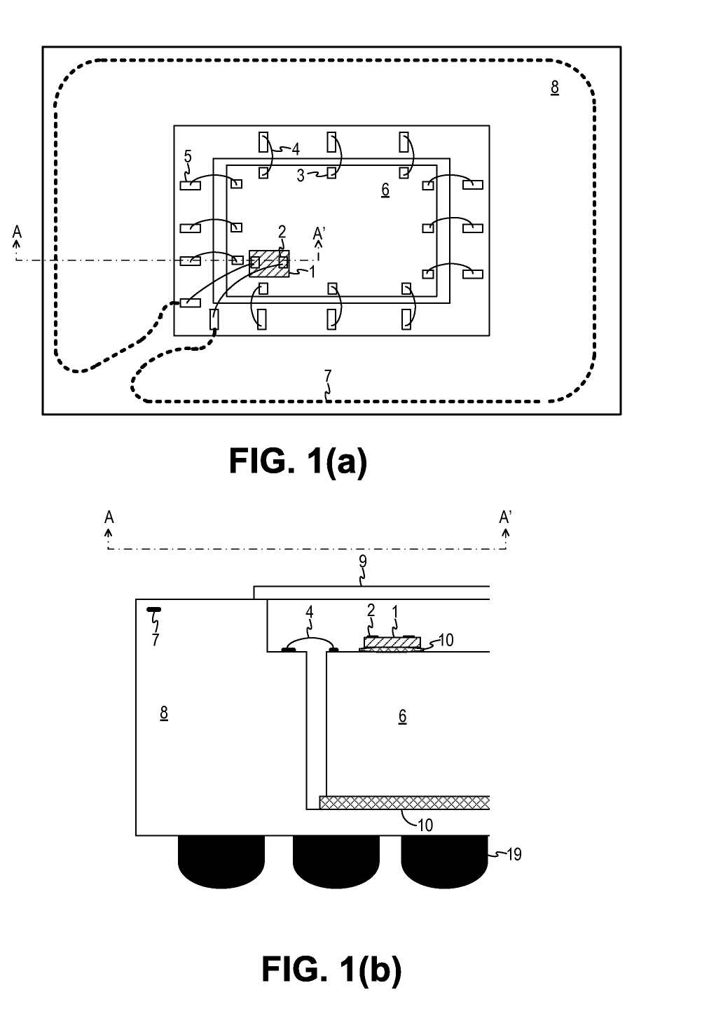

FIGS. 1(a) and 1(b) are top and cross-sectional views, respectively, of a semiconductor package incorporating a wireless communication device (“a wireless tag”) formed using the antenna integration method according to a first embodiment of the present invention. Referring to FIGS. 1(a) and 1(b), a semiconductor package 8 is a lid-sealed cavity integrated circuit package housing an integrated circuit die (“IC die”) 6. In the present embodiment, the semiconductor package 8 is a cavity up BGA package sealed by a package lid 9. IC die 6 is housed in the cavity of semiconductor package 8 and has bonding pads 3 connected to bonding fingers 5 through bond wires 4.

A wireless tag is incorporated in semiconductor package 8 for tracking or authenticating IC die 6. The wireless tag includes a wireless element 1 having at least a wireless transceiver and a memory formed thereon. Wireless element 1 is typically a single integrated circuit die. In the present embodiment, the wireless element 1 is affixed to the top surface of IC die 6 through the use of die attach 10, for example.

An antenna 7 for the wireless tag is formed embedded in the package body of semiconductor package 8. In one embodiment, the antenna 7 is formed as part of the multi-layer interconnect structure of the package body. That is, antenna 7 can be formed simultaneously with the metal interconnects of the semiconductor package. More specifically, semiconductor package 8 includes metal interconnects formed in the package body for connecting the bonding fingers 5 to the external pins, such as solder balls 19. The metal interconnects are formed in the multi-layer interconnect structure of the package body. In accordance with embodiments of the present invention, the antenna 7 is formed using the same metal interconnects and is formed in the available or unused space in the package body of the semiconductor package. The cross-sectional view of FIG. 1(b) along the line A-A′ illustrates the position of antenna 7 in the multi-layer structure of the semiconductor package 8. In this manner, forming antenna 7 does not require additional real estate and antenna 7 is integrated in semiconductor package 8 seamlessly.

The antenna 7 is electrically connected to wireless element 1 to complete the wireless tag circuit. In the present embodiment, the terminals of antenna 7 are connected to bonding fingers 5 of semiconductor package 8. The terminals of the antenna 7 are then electrically connected to bonding pads 2 formed on the wireless element 1 to complete the wireless tag. In one embodiment, the metal interconnect forming antenna 7 is designed to match the impedance of the input and output terminals of the wireless element 1. Furthermore, in some embodiments, the antenna 7 is designed to have a uniform impedance distribution throughout the antenna structure, including the wire bond joints, in order to best match the Input and Output requirements of the wireless element 1 for optimal performance. In some embodiments, antenna 7 can be designed with rounded corners and fewer or no sharp angles. In some embodiments, the bonding fingers connected to the terminals of antenna 7 are selected to be as physically close to each other as possible. In one embodiment, a pair of neighboring bonding fingers is used for connecting to the antenna terminals, as shown in FIG. 1(a). As thus constructed, a wireless tag having wireless element 1 affixed to IC die 6 and antenna 7 formed in the package body of semiconductor package 8 is constructed.

In some embodiments, instead of using bond pads 2 on wireless element 1, a set of bond pads and metal traces can be formed on top of and near the edge of IC die 6 and being connected to the wireless element 1. In that case, the bond wires needed to connect the antenna 7 to the bond pads can be shortened. In some embodiments, such bond pads and metal traces can be formed on top of IC die 6 using metal evaporation, metal sputtering deposition, metal electroplating deposition, conductive ink printing, conductive paste printing method, or other suitable methods. In other embodiments, such bond pads can be part of bond pads 3 of IC die 6.

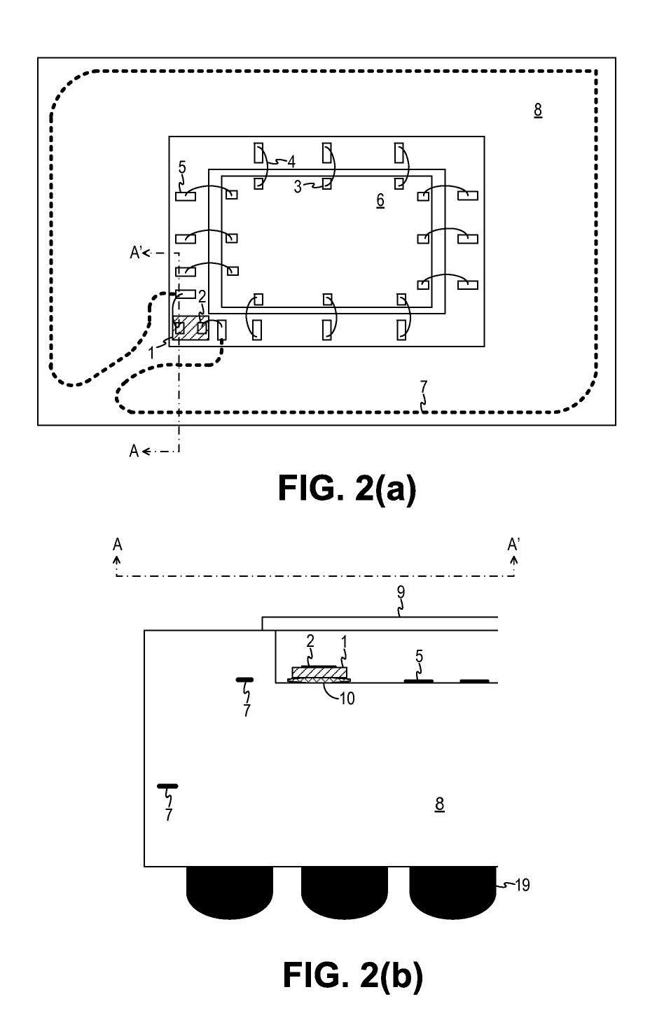

FIGS. 2(a) and 2(b) are top and cross-sectional views, respectively, of a semiconductor package incorporating a wireless communication device (“a wireless tag”) formed using the antenna integration method according to a second embodiment of the present invention. Referring to FIGS. 2(a) and 2(b), a semiconductor package 8 housing an IC die 6 are constructed in the same manner as described above with reference to FIGS. 1(a) and 1(b). A wireless tag includes an antenna 7 formed in the multi-layer package body of the semiconductor package 8 in the same manner as described above. However, in the present embodiment, wireless element 1 is affixed to an inner surface of the package body instead of the IC die 6. In the present embodiment, wireless element 1 is affixed to the package body at a location between the two bonding fingers 5 connecting to antenna 7. In other embodiments, wireless element 1 can be affixed to other locations in the package body suitable for placement of the wireless element and suitable for connection to the antenna.

The cross-sectional view of FIG. 2(b) along the line A-A′ illustrates the formation of antenna 7 in the multi-layer structure of the semiconductor package 8. More specifically, antenna 7 can be formed using one or more metal layers in the multi-layer structure of the semiconductor package 8. In this manner, a desired loop cross-section for antenna 7 can be achieved without increasing the size or footprint of the semiconductor package. In some embodiments, the antenna 7 is designed and formed in the same manner as described above with reference to FIGS. 1(a) and 1(b).

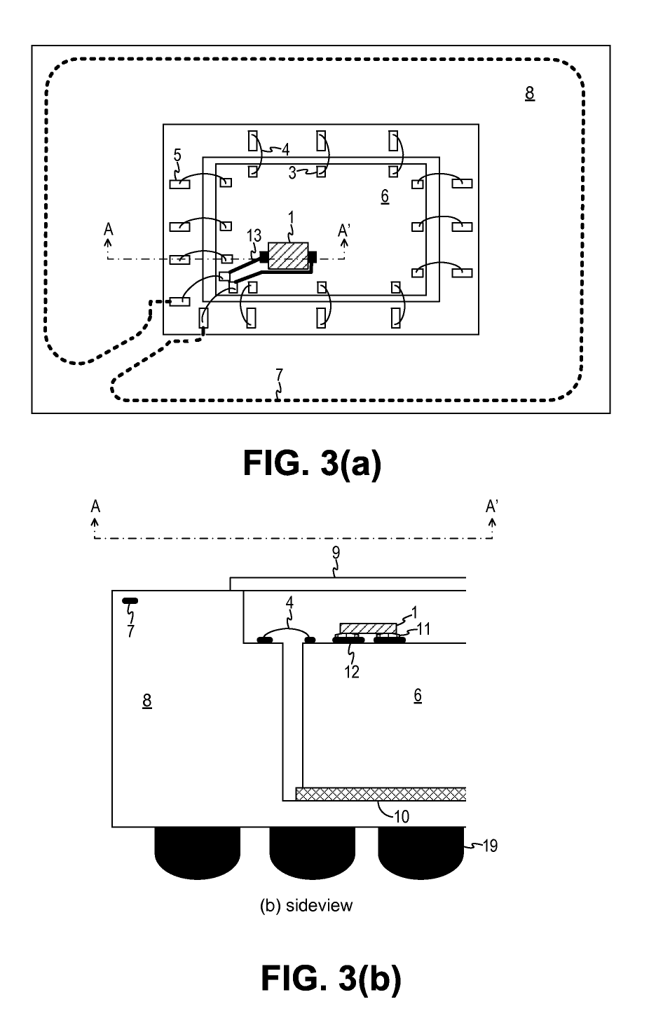

FIGS. 3(a) and 3(b) are top and cross-sectional views, respectively, of a semiconductor package incorporating a wireless communication device (“a wireless tag”) formed using the antenna integration method according to a third embodiment of the present invention. Referring to FIGS. 3(a) and 3(b), a semiconductor package 8 housing an IC die 6 are constructed in the same manner as described above with reference to FIGS. 1(a) and 1(b). A wireless tag includes an antenna 7 formed in the multi-layer package body of the semiconductor package 8 in the same manner as described above. However, in the present embodiment, wireless element 1 is affixed to the IC die 6 through flip-chip attachment. More specifically, solder joints 11 of wireless element 1 are attached to corresponding soldering pads 12 formed on the top surface of IC die 6. Metal interconnect lines 13 formed on the top surface of IC die 6 connect the soldering pads 12 to corresponding bonding pads 3 of IC die 6. Wire bonds are then used to electrically connect the bonding pads 3 connected to the wireless element 1 to the bonding fingers 5 connected to antenna 7.

The soldering pads 12 and the metal interconnect lines 13 can be formed using any one of the metal thin film process described above, including metal evaporation, metal sputtering deposition, metal electroplating deposition, conductive ink printing, conductive paste printing method, or other suitable methods. In other embodiments, the soldering pads 12 are formed as bond pads 3 of IC die 6.

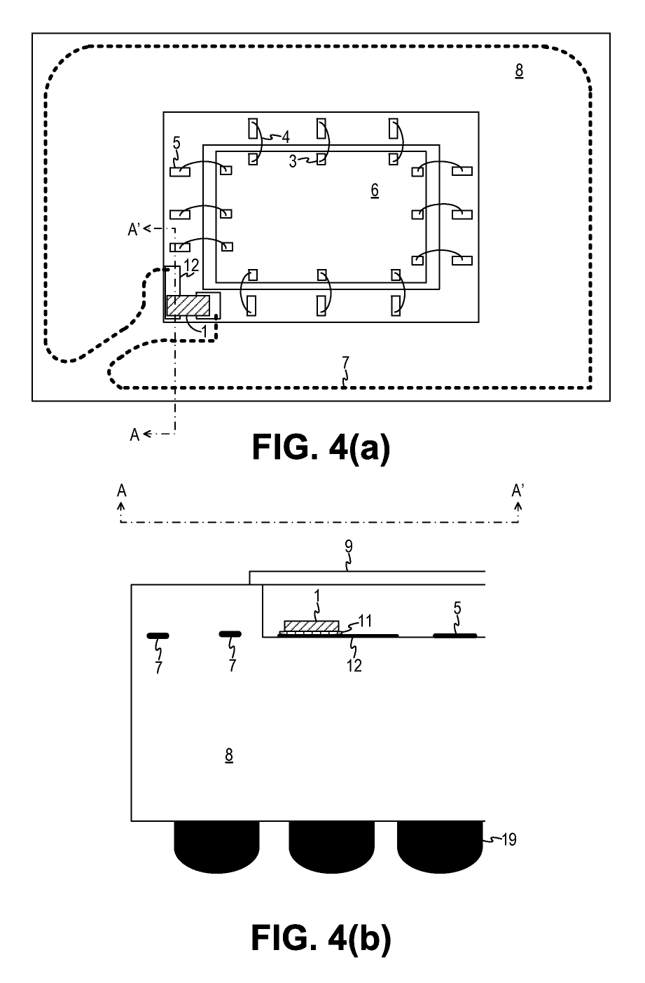

FIGS. 4(a) and 4(b) are top and cross-sectional views, respectively, of a semiconductor package incorporating a wireless communication device (“a wireless tag”) formed using the antenna integration method according to a fourth embodiment of the present invention. Referring to FIGS. 4(a) and 4(b), a semiconductor package 8 housing an IC die 6 are constructed in the same manner as described above with reference to FIGS. 1(a) and 1(b). A wireless tag includes an antenna 7 formed in the multi-layer package body of the semiconductor package 8 in the same manner as described above. However, in the present embodiment, wireless element 1 is affixed to the package body instead of the IC die 6 through flip-chip attachment. More specifically, solder joints 11 of wireless element 1 are attached to corresponding soldering pads 12 (or conductive pads) formed on the package body of semiconductor package 8. Soldering pads 12 can be bonding fingers shaped to accommodate the flip-chip attachment of wireless element 1. The soldering pads 12 are also electrically connected to the antenna 7 formed in the package body of the semiconductor package. In some embodiments, wireless element 1 is connected to soldering pads 12 though solder bumping joints, anisotropic conductive adhesive (ACA), gold bumping, conductive paste connection, or other electrical adhesion methods.

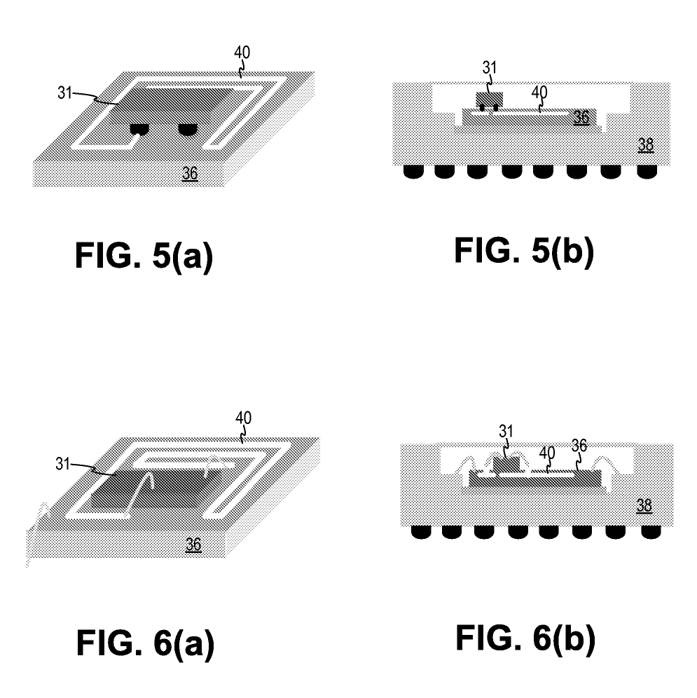

According to another aspect of the present invention, the antenna integration method forms an antenna for a wireless communication device on or in the integrated circuit to which it is affixed. FIGS. 5(a) and 5(b) are perspective and cross-sectional views, respectively, of a semiconductor package incorporating a wireless communication device (“a wireless tag”) formed using the antenna integration method according to a fifth embodiment of the present invention. Referring to FIGS. 5(a) and 5(b), an integrated circuit die (“IC die”) 36 is provided with a wireless communication device for tracking or authenticating the IC die. The IC die 36 is packaged in a lid-sealed cavity integrated circuit package 38. In the present embodiment, the semiconductor package 8 is a cavity up BGA package. IC die 36 is housed in the cavity of semiconductor package 8 and has bonding pads connected to bonding fingers through bond wires (not shown).

A wireless tag is embedded in semiconductor package 38 for tracking or authenticating IC die 36. The wireless tag includes a wireless element 31 having at least a wireless transceiver and a memory formed thereon. Wireless element 31 is typically a single integrated circuit die. In the present embodiment, the wireless element 31 is affixed to the top surface of IC die 36 through flip-chip attachment to a pair of antenna bonding pads formed on the top surface of IC die 36.

An antenna 40 for the wireless tag is formed on or in IC die 36. In one embodiment, antenna 40 is formed using metal traces formed on top of the passivation layer of IC die 36. Alternately, antenna 40 is formed as using one or more metal layers of the IC die 36. Antenna 40 can be formed in the unused space of IC die 36 so that forming antenna 40 in IC die 36 does not increase the size of IC die 36. In either case, antenna bonding pads are formed on the top surface of the passivation layer of IC die 36. The wireless element 31 is attached to the antenna bonding pads to complete the wireless tag circuit. In other embodiments, the antenna bonding pads are part of the bonding pads of IC die 36.

FIGS. 6(a) and 6(b) are perspective and cross-sectional views, respectively, of a semiconductor package incorporating a wireless communication device (“a wireless tag”) formed using the antenna integration method according to a sixth embodiment of the present invention. Referring to FIGS. 6(a) and 6(b), a semiconductor package 38 housing an IC die 36 are constructed in the same manner as described above with reference to FIGS. 5(a) and 5(b). A wireless tag includes an antenna 40 formed on or in the IC die 36 in the same manner as described above. However, in the present embodiment, wireless element 31 is affixed to the IC die 36 face-up and using a die attach. Bond wires are used to connect bonding pads on wireless element 31 to antenna 40 to complete the wireless tag circuit.

In some embodiments, the antenna 40 formed in or on the IC die 36 is constructed in sectors and different length of antenna 40 can be selected to obtain the desired antenna sensitivity. In one embodiment, different antenna length is obtained through bond wire connection.

In other embodiments of the present invention, a wireless communication device utilizes an antenna formed on or in the IC die in conjunction with an antenna embedded in the package body. In this manner, all of the available space of the IC die and the package body can be utilized efficiently to provide an antenna for the wireless communication device having the desired antenna length. In some embodiments, the design and construction of the antenna 40 are in the same manner as described above with reference to FIGS. 1(a) to 4(b).

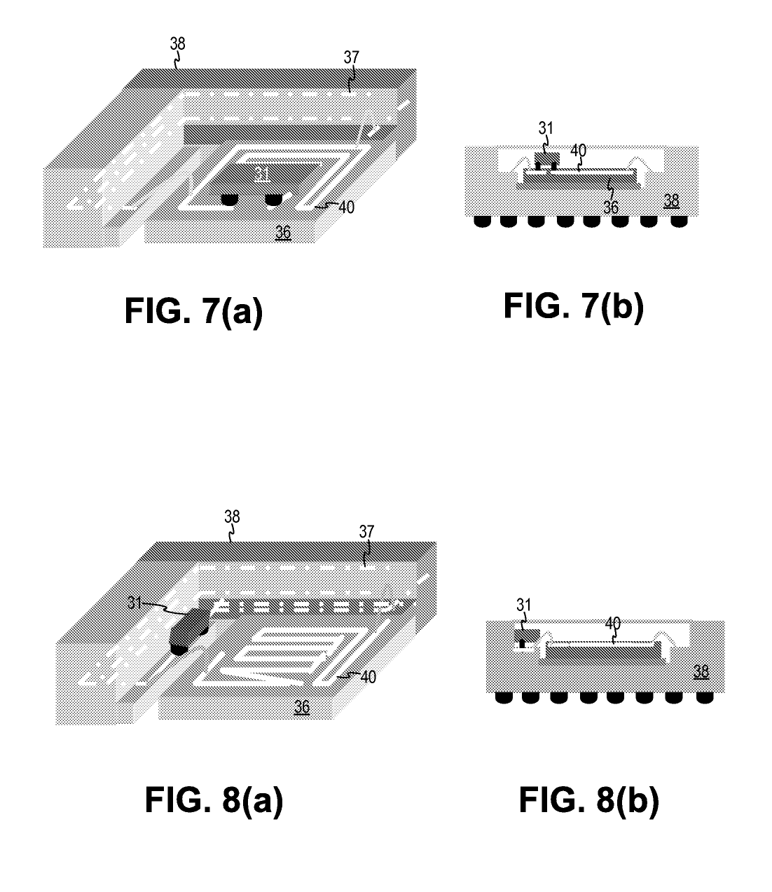

FIGS. 7(a) and 7(b) are perspective and cross-sectional views, respectively, of a semiconductor package incorporating a wireless communication device (“a wireless tag”) formed using the antenna integration method according to a seventh embodiment of the present invention. Referring to FIGS. 7(a) and 7(b), a semiconductor package 38 houses an integrated circuit die 36 to be tracked. An antenna structure 37 is formed in the package body in the same manner as described above. Another antenna structure 40 is formed on or in the IC die 36 also in the same manner as described above. Antenna structure 40 is electrically connected to antenna structure 37, such as through a bond wire. A wireless element 31 is flip-chip attached to antenna bonding pads formed on IC die 36. In this manner, wireless element 31 is connected to antenna 40 formed on or in IC die 36 and also to antenna 37 formed in the package body.

FIGS. 8(a) and 8(b) are perspective and cross-sectional views, respectively, of a semiconductor package incorporating a wireless communication device (“a wireless tag”) formed using the antenna integration method according to an eighth embodiment of the present invention. Referring to FIGS. 8(a) and 8(b), a semiconductor package 38 houses an integrated circuit die 36 and incorporates a wireless element 31 and antenna structures 37 and 40, constructed in the same manner as described above. However, in the present embodiment, wireless element 31 is affixed to antenna bonding pads formed on the package body. In the present illustration, wireless element 31 is flip-chip attached to the inner package surface between the pair of bonding fingers connected to antenna 37. The wireless tag thus constructed is connected to antenna 40 formed on or in IC die 36 and also to antenna 37 formed in the package body.

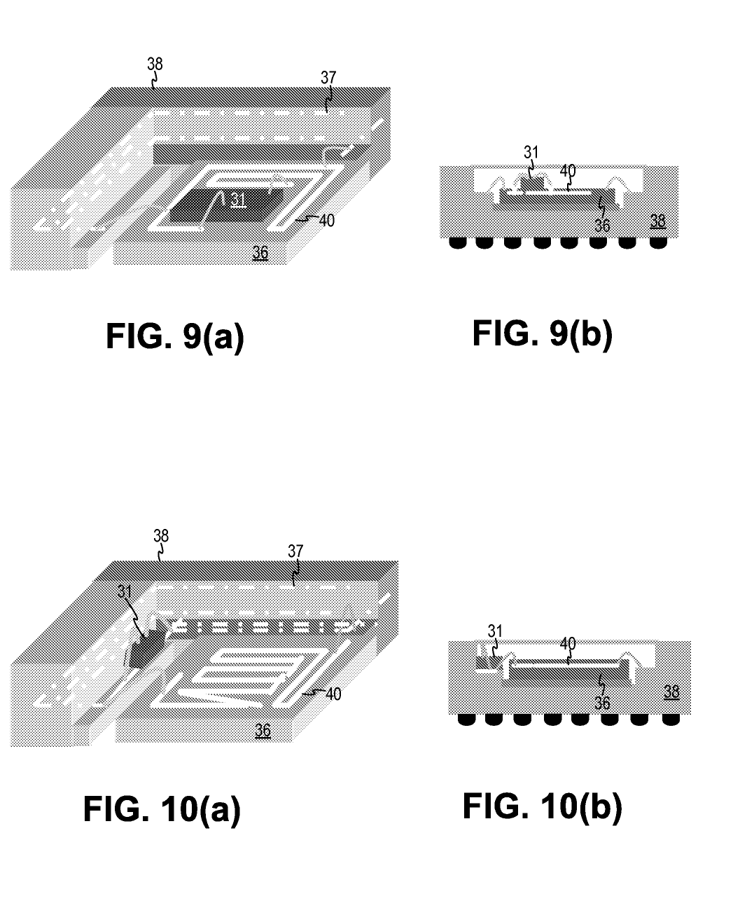

FIGS. 9(a) and 9(b) are perspective and cross-sectional views, respectively, of a semiconductor package incorporating a wireless communication device (“a wireless tag”) formed using the antenna integration method according to a ninth embodiment of the present invention. Referring to FIGS. 9(a) and 9(b), a semiconductor package 38 houses an integrated circuit die 36 and incorporates a wireless element 31 and antenna structures 37 and 40, constructed in the same manner as described above. However, in the present embodiment, wireless element 31 is affixed to the IC die 36 face-up and using a die attach. Bond wires are used to connect bonding pads on wireless element 31 to antenna 40 to complete the wireless tag circuit. The wireless tag thus constructed is connected to antenna 40 formed on or in IC die 36 and also to antenna 37 formed in the package body.

FIGS. 10(a) and 10(b) are perspective and cross-sectional views, respectively, of a semiconductor package incorporating a wireless communication device (“a wireless tag”) formed using the antenna integration method according to a tenth embodiment of the present invention. Referring to FIGS. 10(a) and 10(b), a semiconductor package 38 houses an integrated circuit die 36 and incorporates a wireless element 31 and antenna structures 37 and 40, constructed in the same manner as described above. However, in the present embodiment, wireless element 31 is affixed to antenna bonding pads formed on the package body. In the present illustration, wireless element 31 is affixed to the inner package surface between the pair of bonding fingers connected to antenna 37 with the face-up orientation and using a die attach. Bond wires are used to connect bonding pads on wireless element 31 to antenna 37 to complete the wireless tag circuit. The wireless tag thus constructed is connected to antenna 40 formed on or in IC die 36 and also to antenna 37 formed in the package body.

An advantage of the antenna integration methods described above is that the size of the antenna can be increased without increasing the size of the housing of the device. When the antenna size of the wireless tag is increased, the wireless tag can recover more wireless signal energy to facilitate the operation of the wireless transceiver and memory circuits and to increase its transmission power. Another advantage of the antenna integration method of the present invention is that embedding the wireless element does not require additional I/O leads for the IC package. Therefore, the IC and the semiconductor package can retain their original size even when the wireless element and the antenna structure are embedded in the semiconductor package.

In some embodiments, to accommodate the tight form factor associated with the IC package, the wireless element of the wireless tag can be background to a thinner thickness to cope with this space constraint and facilitate the standard IC package assembly process.

According to another aspect of the present invention, the antenna structure is extended onto the external printed circuit board through IC package I/O pins to improve the performance sensitivity and sensing range of the wireless communication device.

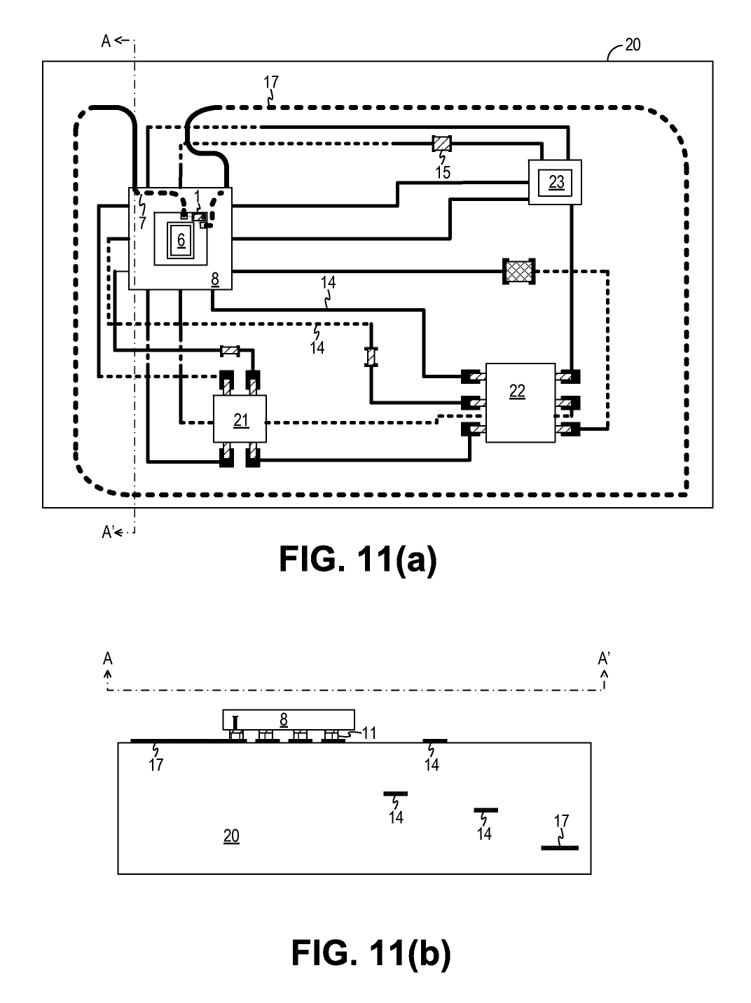

FIGS. 11(a) and 11(b) are top and cross-sectional views, respectively, of a printed circuit board with extended antenna structure incorporating a semiconductor package incorporating a wireless communication device (“a wireless tag”) formed using the antenna integration method and according to an eleventh embodiment of the present invention. Referring to FIGS. 11(a) and 11(b), a printed circuit board (PCB) 20 has mounted thereon multiple semiconductor packages each housing one or more integrated circuits therein. PCB 20 includes a semiconductor package 8 having a wireless element 1 and an antenna embedded therein. The PCB 20 also includes other semiconductor packages 21-23 and/or other discrete components 15 mounted thereon. The integrated circuits and discrete components are interconnected through metal traces 14 formed on the PCB.

In one embodiment of the present invention, an antenna 17 is formed on the PCB 20 and is connected to the antenna 7 formed embedded in semiconductor package 8. Antenna 17 is formed as part of the metal interconnect structure of PCB 20 and makes use of the available space in PCB 20. Thus, the wireless tag embedded in semiconductor package 8 can be provided with an extended antenna structure without increasing the size of the PC board. In one embodiment, antenna 17 is connected to the embedded antenna 7 through a pair of I/O leads of semiconductor package 8.

As shown in the cross-sectional view of FIG. 11(b), antenna 17 can be formed on a single metal plane or multiple metal planes of the PCB 20. Also antenna 17 can assume any shape, such as rectangular, circular and spiral shapes. Antenna 17 can be made of any conductive materials, including copper or aluminum. In some embodiments, antenna 17 is designed without any sharp corners or turns and antenna 17 is formed using a homogeneous material. In some embodiments, the impedance of antenna 17 can be controlled in a way to better match the impedance character of the Input and output terminal of the wireless element when joined together with antenna 7. In some embodiments, the design and construction of the antenna 17 are carried out in the same manner as described above for the package level antenna integration method.

In the above described embodiments, the semiconductor package is shown as housing a single integrated circuit die only. The single-die semiconductor package is illustrative only. The antenna integration method described above can be applied to semiconductor packages housing two or more integrated circuit die, such as multi-chip packages.

In embodiments of the present invention, the wireless communication device stores at least identity or identification information of the microelectronic device in the memory of the wireless element of the wireless tag. In other embodiments, the wireless communication device stores at least identity or identification information of the derivative system products incorporating the microelectronic device in the memory of the wireless element of the wireless tag. In the present description, “identity” or “identification information” of a microelectronic device at least includes the identification number, part number, model number, model name, brand name, maker, logo design, and production and/or distribution history of the microelectronic device. Furthermore, identity or identification information can include a software code or an algorithm to generate an identity code in response to interrogations from a wireless reader or other systems. In embodiments of the present invention, the data format of the identification information includes a random or serial numerical numbers or characters, logo marks, graphic symbols, 2D graphic codes, or any multiplex permutation of these formats. Other encoding or algorithms methods currently known or to be developed can also be used. In an alternate embodiment, the identity or identification information stored in the wireless element is protected through the use of encryption or software keys or other feasible security protection methods presently known or to be developed.

Also, in the present embodiment, the wireless communication device is capable of wireless communication employing one or more of the wireless communication technologies currently known or to be developed. For example, in one embodiment, the wireless communication device implements wireless communication through radio frequency (RF) communication, such as based on the RFID (radio frequency identification) technology, or wireless local area network communication technology, such as Wi-Fi technology. In another embodiment, the wireless communication device employs Bluetooth radio technology. Bluetooth radio technology is an open specification for short-range wireless communication of data and voice that operates in the unlicensed Industrial, Scientific, Medical (ISM) band at 2.4 Gigahertz (GHz). The gross data rate may be 1 megabit per second (Mb/s). In yet another embodiment, the wireless communication device employs ZigBee communication technology. ZigBee is a wireless control technology utilizing a low-cost, low power, wireless mesh networking protocol that is especially useful in control and monitoring applications. In yet another embodiment, the wireless communication device employs WiMAX communication.

The above detailed descriptions are provided to illustrate specific embodiments of the present invention and are not intended to be limiting. Numerous modifications and variations within the scope of the present invention are possible. The present invention is defined by the appended claims.

I claim:

1. A semiconductor package, comprising:
a package body including a cavity;
a first integrated circuit die housed in the cavity and electrically connected to leads of the semiconductor package;
a wireless element including a wireless transceiver and a memory circuit both formed in a second integrated circuit die, the wireless element being housed in the semiconductor package; and
an antenna embedded in the package body and electrically connected to the wireless element,
wherein the wireless transceiver and the antenna operate in conjunction to enable the information stored in the memory circuit to be accessed through wireless communication.

2. The semiconductor package of claim 1, wherein the package body comprises a multi-layer interconnect structure including interleaving metal films and dielectric films; and the antenna is formed as part of the multi-layer interconnect structure using one or more of the metal films.

3. The semiconductor package of claim 1, wherein the wireless element is affixed to a top surface of the first integrated circuit die.

4. The semiconductor package of claim 3, wherein the wireless element is affixed to the top surface of the first integrated circuit die using a die attach and the wireless element comprises bonding pads formed on a top surface of the wireless element, the bonding pads being electrically connected to terminals of the antenna using bond wires.

5. The semiconductor package of claim 3, wherein the wireless element is affixed to the top surface of the first integrated circuit die using flip-chip attachment and the wireless element is electrically connected to terminals of the antenna using bond wires and metal traces formed on the top surface of the first integrated circuit die.

6. The semiconductor package of claim 1, wherein the wireless element is affixed to an inner surface of the package body.

7. The semiconductor package of claim 6, wherein the wireless element is affixed to the inner surface of the package body using a die attach and the wireless element comprises bonding pads formed on a top surface of the wireless element, the bonding pads being electrically connected to terminals of the antenna using bond wires.

8. The semiconductor package of claim 6, wherein the wireless element is affixed to the inner surface of the package body using flip-chip attachment and the wireless element is electrically connected to terminals of the antenna through solder joints connected to conductive pads or bonding fingers of the package body.

9. The wireless tag of claim 1, wherein the wireless transceiver comprises a radio frequency (RF) transceiver.

10. A semiconductor package, comprising:
a package body including a cavity;
a first integrated circuit die housed in the cavity and electrically connected to leads of the semiconductor package;
a wireless element including a wireless transceiver and a memory circuit both formed in a second integrated circuit die, the wireless element being housed in the semiconductor package; and
an antenna formed on or in the first integrated circuit die and electrically connected to the wireless element,
wherein the wireless transceiver and the antenna operate in conjunction to enable the information stored in the memory circuit to be accessed through wireless communication.

11. The semiconductor package of claim 10, wherein the antenna is formed as metal traces on a passivation layer of the first integrated circuit die.

12. The semiconductor package of claim 10, wherein the antenna is formed using one or more of the metal layers of the first integrated circuit die.

13. The semiconductor package of claim 10, wherein the wireless element is affixed to the top surface of the first integrated circuit die using a die attach and the wireless element comprises bonding pads formed on a top surface of the wireless element, the bonding pads being electrically connected to terminals of the antenna using bond wires.

14. The semiconductor package of claim 10, wherein the wireless element is affixed to the top surface of the first integrated circuit die using flip-chip attachment and the wireless element is electrically connected to terminals of the antenna using solder joints and metal traces formed on the top surface of the first integrated circuit die.

15. The semiconductor package of claim 10, further comprising a second antenna embedded in the package body and electrically connected to the antenna formed on or in the first integrated circuit die.

16. The semiconductor package of claim 15, wherein the wireless element is affixed to an inner surface of the package body.

17. The semiconductor package of claim 16, wherein the wireless element is affixed to the inner surface of the package body using a die attach and the wireless element comprises bonding pads formed on a top surface of the wireless element, the bonding pads being electrically connected to terminals of the second antenna using bond wires.

18. The semiconductor package of claim 6, wherein the wireless element is affixed to the inner surface of the package body using flip-chip attachment and the wireless element is electrically connected to terminals of the second antenna through conductive pads formed on the top surface of the first integrated circuit die.

19. A printed circuit board, comprising:
one or more semiconductor packages mounted thereon, each semiconductor package housing an integrated circuit die;
a first semiconductor package comprising:
a first integrated circuit die electrically connected to leads of the semiconductor package;
a wireless element including a wireless transceiver and a memory circuit both formed on a second integrated circuit die, the wireless element being housed in the semiconductor package; and
a first antenna embedded in the package body and electrically connected to the wireless element;
a second antenna formed in the printed circuit board and being electrically connected to the first antenna,
wherein the wireless transceiver and the first and second antennas operate in conjunction to enable the information stored in the memory circuit to be accessed through wireless communication.

20. The printed circuit board of claim 19, wherein the second antenna is formed in one or more metal planes of the printed circuit board.

21. The printed circuit board of claim 19, wherein terminals of the second antenna is electrically connected to a first set of leads of the first semiconductor package, the first set of leads being electrically connected to terminals of the first antenna embedded in the package body of the semiconductor package.
